(19) United States
(12) Patent Application Publication
(10) Pub. No.: US 2026/0068441 A1
(43) Pub. Date: Mar. 5, 2026

(54) DISPLAY PANEL AND DISPLAY APPARATUS

(71) Applicant: HKC CORPORATION LIMITED, SHENZHEN (CN)

(72) Inventors: Qin LIANG, SHENZHEN (CN); Zhisheng XIE, SHENZHEN (CN); Yangling TANG, SHENZHEN (CN); Xiufeng ZHOU, SHENZHEN (CN); Lidan YE, SHENZHEN (CN)

(73) Assignee: HKC CORPORATION LIMITED, SHENZHEN (CN)

(21) Appl. No.: 19/299,815

(22) Filed: Aug. 14, 2025

(30) Foreign Application Priority Data
Aug. 30, 2024 (CN) 202411218991.0

(51) Int. Cl. H10K 59/122; H10K 59/123

(52) U.S. Cl. CPC H10K 59/122; H10K 59/123

(57) ABSTRACT

The present application relates to the field of optical display technologies, and in particular to a display panel and a display apparatus. A metal layer may electrically connect with a first connecting wire by a jumper wire through a first via, so as to conduct electrical signal transmission between the metal layer and the first connecting wire. A portion of the first connecting wire may coincide with a pixel definition layer, so that the portion of the first connecting wire may be covered by the pixel definition layer. A portion of the metal layer that passes through the first via may be surrounded and wrapped by the pixel definition layer. Therefore, the pixel definition layer may protect a portion of the first connecting wire and a junction between the metal layer and the first connecting wire.

### CROSS REFERENCE TO RELATED APPLICATIONS

This application claims priority to Chinese Patent Application No. 202411218991.0, entitled “display panel and display apparatus”, filed on Aug. 30, 2024, which is herein incorporated by reference in its entirety.

### TECHNICAL FIELD

The present disclosure relates to the field of optical display technologies, and in particular to a display panel and a display apparatus.

### BACKGROUND

Stretchable display technologies may enable a display screen to have ductility, be stretched in various directions to change its shape, and adapt to surfaces of any shape. Stretchable screens may be flexibly applied in various fields, such as consumer electronics, public display, medical, biological, wearable, gaming, fashion, and in-vehicle scenarios, or the like. In existing stretchable display technologies, a design of signal transmission in an extension region may mostly involve connecting metal layers of adjacent spacer structures through connecting wires made of metal materials. Therefore, how to enable the connecting wires to perform effective and stable signal transmission is a technical problem that urgently needs to be solved.

### SUMMARY

According a first aspect of the present disclosure, a display panel may be provided. The display panel may include a driving substrate, a pixel definition layer, a sub-pixel, a spacer structure, and a first connecting wire. The driving substrate may form a pixel region and an extension region. The pixel definition layer may be arranged on the driving substrate. The pixel definition layer may be configured to protrude from the driving substrate to define a pixel aperture. The sub-pixel may be arranged in the pixel aperture. The sub-pixel may include an anode electrode, a light-emitting layer and a cathode electrode. The anode electrode, the light-emitting layer and the cathode electrode may be stacked from a position close to the driving substrate to another position away from the driving substrate. The spacer structure may be arranged on the pixel definition layer and located on a peripheral side of the pixel aperture to separate the pixel region from the extension region. The spacer structure may include a metal layer and an insulating layer. The metal layer and the insulating layer may be stacked from a position close to the pixel definition layer to another position away from the pixel definition layer. The first connecting wire may be arranged on the driving substrate. The first connecting wire may extend from the extension region to the pixel region. The first connecting wire may be insulated from the anode electrode. An orthographic projection of the first connecting wire onto the driving substrate may at least partially coincide with an orthographic projection of the pixel definition layer onto the driving substrate, so as to form a first coinciding region. The pixel definition layer may form a first via in the first coinciding region. The metal layer may electrically connect with the first connecting wire through the first via.

According to a second aspect of the present disclosure, a display apparatus may be provided. The display apparatus may include a display panel and a power supply. The display panel may include a driving substrate, a pixel definition layer, a sub-pixel, a spacer structure, and a first connecting wire. The driving substrate may form a pixel region and an extension region. The pixel definition layer may be arranged on the driving substrate. The pixel definition layer may be configured to protrude from the driving substrate to define a pixel aperture. The sub-pixel may be arranged in the pixel aperture. The sub-pixel may include an anode electrode, a light-emitting layer and a cathode electrode. The anode electrode, the light-emitting layer and the cathode electrode may be stacked from a position close to the driving substrate to another position away from the driving substrate. The spacer structure may be arranged on the pixel definition layer and located on a peripheral side of the pixel aperture to separate the pixel region from the extension region. The spacer structure may include a metal layer and an insulating layer. The metal layer and the insulating layer may be stacked from a position close to the pixel definition layer to another position away from the pixel definition layer. The first connecting wire may be arranged on the driving substrate. The first connecting wire may extend from the extension region to the pixel region. The first connecting wire may be insulated from the anode electrode. An orthographic projection of the first connecting wire onto the driving substrate may at least partially coincide with an orthographic projection of the pixel definition layer onto the driving substrate, so as to form a first coinciding region. The pixel definition layer may form a first via in the first coinciding region. The metal layer may electrically connect with the first connecting wire through the first via.

### BRIEF DESCRIPTION OF THE DRAWINGS

Accompanying drawings herein are incorporated into and form a part of the present specification, illustrate embodiments consistent with the present disclosure, and are used together with the specification to explain principles of the present disclosure. Obviously, the drawings in the following description are only some embodiments of the present disclosure. For those of ordinary skills in the art, other drawings may be further obtained based on these drawings without creative efforts.

FIG. 1 is a first schematic structural diagram of a display panel according to some embodiments of the present disclosure.

FIG. 2 is a schematic cross-sectional view along a direction A-A of FIG. 1.

FIG. 3 is a second schematic structural diagram of a display panel according to some embodiments of the present disclosure.

FIG. 4 is a schematic cross-sectional view along a direction B-B of FIG. 3, with shielding portions being formed on both sides of a spacer structure.

FIG. 5 is a schematic cross-sectional view of a display panel according to some embodiments of the present disclosure, in which case the display panel includes a first connecting wire and a second connecting wire, and a first via is defined in a pixel region.

FIG. 6 is a schematic cross-sectional view of a display panel according to some embodiments of the present disclosure, in which case the display panel includes a first connecting wire and a second connecting wire, a first via is defined in an extension region.

FIG. 7 is a schematic cross-sectional view along a direction B-B of FIG. 3, wherein a shielding portion is formed on one side of a spacer structure facing a pixel aperture.

FIG. 8 is a schematic structural block of a display apparatus according to some embodiments of the present disclosure.

### DETAILED DESCRIPTION

Example implementations will now be described more thoroughly with reference to accompanying drawings. However, the example implementations may be implemented in a variety of forms, and should not be construed as being limited to the examples set forth herein. Rather, these embodiments may be provided to make the present disclosure more comprehensive and complete, and to communicate ideas of the example implementations to those skilled in the art in a comprehensive manner.

In addition, features, structures or characteristics described may be combined in one or more embodiments in any suitable manner. In the following description, many specific details may be provided, so as to offer a full understanding of embodiments of the present disclosure. However, those skilled in the art will appreciate that, it is possible to practice technical schemes of the present disclosure while omitting one or more of the particular details described, or other methods, components, apparatuses, steps, or the like may be adopted. In other cases, well-known methods, apparatuses, implementations, or operations may not be illustrated or described in detail, so as to avoid obscuring various aspects of the present disclosure.

The following may provide a further detailed description of the present disclosure in conjunction with the accompanying drawings and specific embodiments. It should be noted herein that, technical features involved in various embodiments of the present disclosure described below may be combined with each other as long as there is no mutual conflict. The embodiments described below with reference to the accompanying drawings are exemplary and are intended to explain the present disclosure, and should not be construed as limiting the present disclosure.

It should be noted that, the term “a plurality of” recited herein means two or more than two. The term “and/or” is used to describe an associating relationship of the associated objects, and may indicate that there could be three relationships between the associated objects. For example, A and/or B may represent three situations: only A exists, A and B exist simultaneously, and only B exists. The character “/” may generally indicate an “or” relationship between the associated terms before and after the character “/”.

Stretchable display technologies may enable a display screen to have ductility, be stretched in various directions to change its shape, and adapt to surfaces of any shape. Stretchable screens may be flexibly applied in various fields, such as consumer electronics, public display, medical, biological, wearable, gaming, fashion, and in-vehicle scenarios, or the like. In existing stretchable display technologies, a design of signal transmission in an extension region may mostly involve connecting metal layers of adjacent spacer structures through connecting wires made of metal materials. Therefore, how to enable the connecting wires to perform effective and stable signal transmission is a technical problem that urgently needs to be solved.

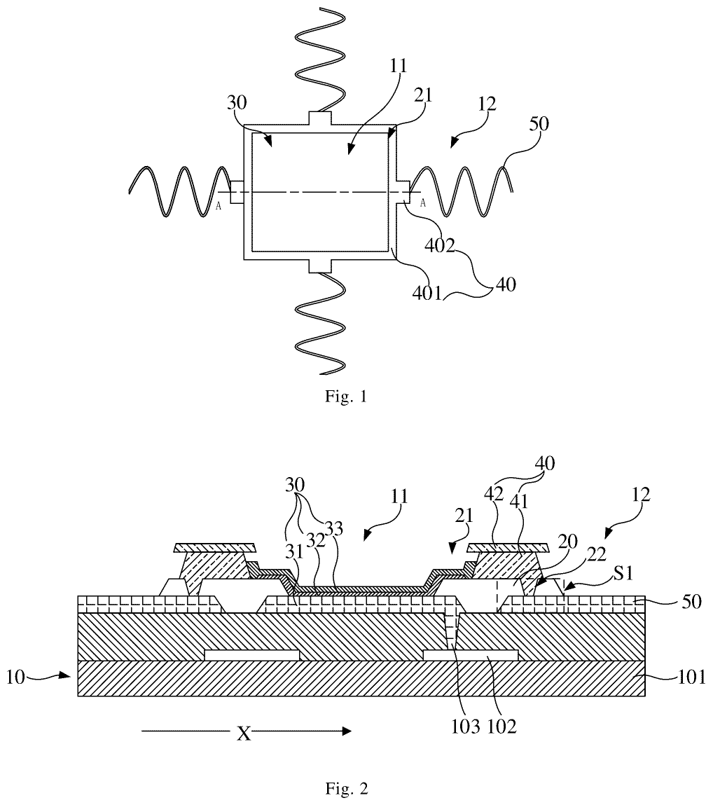

For solving the above-mentioned technical problem, some embodiments of the present disclosure may provide a display panel. As illustrated in FIG. 1 and FIG. 2, the display panel may include a driving substrate 10, a pixel definition layer 20, a sub-pixel 30, a spacer structure 40, and a first connecting wire 50. The driving substrate 10 may form a pixel region 11 and an extension region 12. The pixel definition layer 20 may be arranged on the driving substrate 10. The pixel definition layer 20 may protrude from the driving substrate 10 to define a pixel aperture 21. A sub-pixel 30 may be arranged in the pixel aperture 21. The sub-pixel 30 may include an anode electrode 31, a light-emitting layer 32, and a cathode electrode 33. The anode electrode 31, the light-emitting layer 32, and the cathode electrode 33 may be stacked from a position close to the driving substrate 10 to another position away from the driving substrate 10. The spacer structure 40 may be arranged on the pixel definition layer 20 and located on a peripheral side of the pixel aperture 21, so as to separate the pixel region 11 from the extension region 12. In some embodiment, the extension region 12 may be on a side of the spacer structure 40 away from the pixel aperture 21. The spacer structure 40 may include a metal layer 41 and an insulating layer 42. The metal layer 41 and the insulating layer 42 may be stacked or laminatingly arranged from a position close to the pixel definition layer 20 to another position away from the pixel definition layer 20. The first connecting wire 50 may be arranged on the driving substrate 10. The first connecting wire 50 may extend from the extension region 12 to the pixel region 11. The first connecting wire 50 may be insulated from the anode electrode 31. An orthographic projection of the first connecting wire 50 onto the driving substrate 10 may at least partially coincide with an orthographic projection of the pixel definition layer 20 onto the driving substrate 10, so as to form a first coinciding region S1. The pixel definition layer 20 may form a first via 22 in the first coinciding region S1. The metal layer 41 may pass through the first via 22 to electrically connect with the first connecting wire 50.

As illustrated in FIG. 1 and FIG. 2, the pixel region 11 formed on the driving substrate 10 may be configured for arrangement of a pixel unit. The extension region 12 may be configured to provide compensation when the display panel is stretched. The pixel unit may include the pixel definition layer 20, the sub-pixel 30, and the spacer structure 40. The spacer structure 40 may be configured to separate adjacent sub-pixels 30 to achieve independent packaging. The spacer structure 40 may separate the extension region 12 from the anode electrode 31, the light-emitting layer 32, and the cathode electrode 33 of the sub-pixel 30. The light-emitting layer 32 may emit light under driving of the anode electrode 31 and the cathode electrode 33. The spacer structure 40 may include the metal layer 41 and the insulating layer 42. The display panel may further include the first connecting wire 50 arranged on the driving substrate 10. The first connecting wire 50 may be insulated from the anode electrode 31 to reduce signal interference between the first connecting wire 50 and the anode electrode 31. The pixel definition layer 20 may form the first via 22 in the first coinciding region S1. The metal layer 41 may be electrically connected to the cathode electrode 33. The metal layer 41 may pass through the first via 22 to electrically connect with the first connecting wire 50, such that a cathode electrode 33 signal may be transmitted to the first connecting wire 50 through the metal layer 41. Through such a design, the first connecting wire 50 and the anode electrode 31 may be arranged on a same layer. The first connecting wire 50 and the anode electrode 31 may be formed through a same process and of a same material. In this way, a differentiation of the first connecting wire 50 may be reduced, and the number of manufacturing procedures may be decreased. Moreover, the metal layer 41 may be electrically connected to the first connecting wire 50 by a jumper wire through the first via 22, so as to conduct electrical signal transmission between the metal layer 41 and the first connecting wire 50. A portion of the first connecting wire 50 may coincide with the pixel definition layer 20, so that the portion of the first connecting wire 50 may be covered by the pixel definition layer 20. The portion of the metal layer 41 that passes through the first via 22 may be surrounded and wrapped by the pixel definition layer 20. Therefore, the pixel definition layer 20 may protect the portion of the first connecting wire 50 and a junction between the metal layer 41 and the first connecting wire 50. When the display panel is stretched, a risk of disconnection between the metal layer 41 and the first connecting wire 50 may be reduced, thereby increasing effectiveness and stability of the signal transmission of connecting wires.

In some embodiments, as illustrated in FIG. 1 and FIG. 2, a plurality of pixel regions 11 and a plurality of extension regions 12 may be formed on the driving substrate 10. The pixel regions 11 may be arranged at intervals. The extension regions 12 may be arranged at intervals. The pixel regions 11 and the extension regions 12 may be arranged alternately in a same direction. When the display panel is stretched, the extension regions 12 arranged at intervals may be deformed. The extension regions 12 may become longer in a stretching direction, while the area of the pixel regions 11 may not change, so as to realize stretching of the display screen. Through the plurality of extension regions 12, the display screen may be enabled to be stretched to a larger area, thereby increasing the display area of the display screen.

In some embodiments, as illustrated in FIG. 2, the driving substrate 10 may include a flexible base 101 and a driving circuit 102. The flexible base 101 may be a glass flexible base 101 or an organic flexible base 101. The driving circuit 102 may be a thin film transistor (TFT) circuit layer. The TFT circuit layer may be configured to drive the light-emitting layer 32 of an OLED. In some embodiments, the TFT circuit layer may include a plurality of driving circuit units arranged in an array. Each driving circuit 102 unit may include a TFT device and a capacitor. Each driving circuit 102 unit may match with one anode electrode 31 and with one organic light-emitting layer 32. The TFT device may be of a low temperature poly-silicon (LTPS) type or a metal-oxide semiconductor (MOS) type. The MOS type may such as be a metal-oxide semiconductor type of an indium gallium zinc oxide (IGZO).

In some embodiments, as illustrated in FIG. 2, the display panel may further include a pad 103. The pad 103 may be configured to connect the driving circuit 102 and the anode electrode 31 and to transmit electrical signals.

In some embodiments, a material of the pixel definition layer 20 may be one of an organic material, an organic material with an inorganic coating thereon, or an inorganic material. The organic material of the pixel definition layer 20 may include but be not limited to polyimide. The inorganic materials of the pixel definition layer 20 may include but be not limited to silicon oxide (SiO), silicon nitride (SiN), silicon oxynitride (SiNO), magnesium fluoride (MgF) or a combination thereof.

In some embodiments, as illustrated in FIG. 1, the spacer structure 40 may include a body portion 401 and a first reinforcing portion 402. The first reinforcing portion 402 may be formed by extending from the body portion 401 towards a side away from the pixel aperture 21. The width of the first reinforcing portion 402 is greater than that of the body portion 401 in a direction from the pixel aperture 21 to the extension region 12. The first connecting wire 50 may be connected to the first reinforcing portion 402. Through forming the first reinforcing portion 402 in the spacer structure 40, a connection strength between the first connecting wire 50 and the spacer structure 40 may be increased, and a risk of the first connecting wire 50 disconnecting from the spacer structure 40 due to the stretching of the display panel may be reduced, thereby increasing a connection stability between the first connecting wire 50 and the spacer structure 40.

In some embodiments, as illustrated in FIG. 2, the first connecting wire 50 and the anode electrode 31 may be arranged in the same layer on the driving substrate 10. The first connecting wire 50 and the anode electrode 31 may be formed by deposition using the same material. During the deposition process, the anode electrode 31 and the first connecting wire 50 may be kept at an interval to insulate them from each other. When the pixel definition layer 20 is formed in subsequent processes, the pixel definition layer 20 may be formed at the interval between the anode electrode 31 and the first connecting wire 50.

In some embodiments, as illustrated in FIG. 2, the orthographic projection may refer to a projection generated when parallel projection lines are perpendicular to a projection plane. The orthographic projection of the first connecting wire 50 onto the driving substrate 10 may at least partially coincide with the orthographic projection of the pixel definition layer 20 onto the driving substrate 10, so as to form the first coinciding region S1. In other words, the first connecting wire 50 and the pixel definition layer 20 may at least partially coincide on the driving substrate 10 in a vertical direction, so that at least a part of the pixel definition layer 20 may cover the first connecting wire 50.

In some embodiments, the first connecting wire 50 and the pixel definition layer 20 may partially coincide. In other words, a length of the pixel definition layer 20 may be less than that of the first connecting wire 50 in a length direction X of the driving substrate 10 as illustrated in FIG. 2. The pixel definition layer 20 and the first connecting wire 50 may be arranged to be overlapped. The first connecting wire 50 and the pixel definition layer 20 may completely coincide (hereinafter simply referred to as coincide). That is, the width of the pixel definition layer 20 may be greater than that of the first connecting wire 50 in a direction perpendicular to the length direction X of the driving substrate 10. The pixel definition layer 20 may completely cover the part of the first connecting wire 50 under the pixel definition layer 20.

In some embodiments, the first via 22 may be formed by etching the pixel definition layer 20. The pore diameter of the first via 22 may gradually decrease in a direction from a position away from the driving substrate 10 to another position close to the driving substrate 10. The first via 22 may be formed to provide a space for downward deposition of the metal layer 41 when the metal layer 41 is deposited later, so that the metal layer 41 may be in contact with the first connecting wire 50, and the metal layer 41 may be electrically connected to the first connecting wire 50.

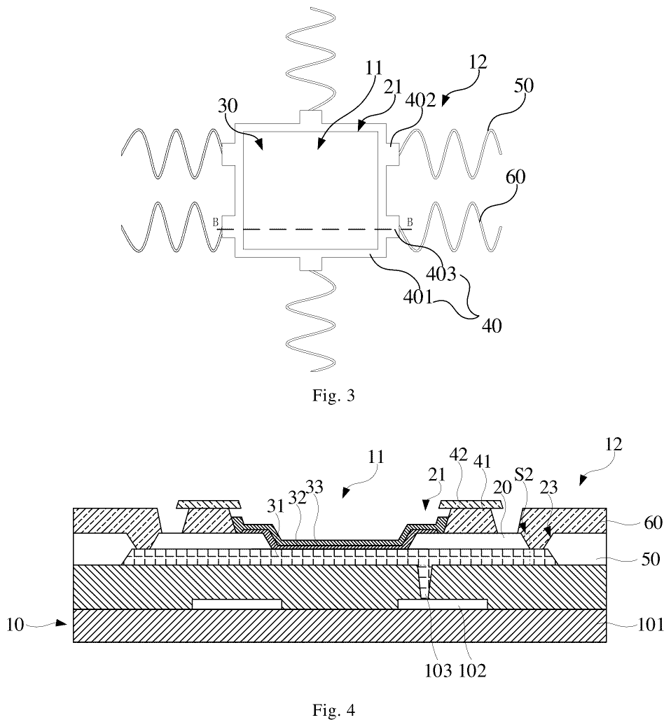

In some embodiments, as illustrated in FIG. 3 and FIG. 4, a portion of the anode electrode 31 may extend from the pixel region 11 to the extension region 12. On one side of the spacer structure 40 facing the extension region 12, an orthographic projection of the anode electrode 31 onto the driving substrate 10 may at least partially coincide with that of the pixel definition layer 20 onto the driving substrate 10, so as to form a second coinciding region S2. The pixel definition layer 20 may form a second via 23 in the second coinciding region S2. The display panel may further include a second connecting wire 60. The second connecting wire 60 may be arranged on a side of the pixel definition layer 20 opposite to the driving substrate 10. The second connecting wire 60 may be insulated from the metal layer 41. The second connecting wire 60 may pass through the second via 23 to electrically connect with the anode electrode 31. In this way, a portion of the anode electrode 31 may extend from the pixel region 11 to the extension region 12, such that a width of the portion of the anode electrode 31 may be wider than that of another portion of the anode electrode 31. The orthographic projection of the anode electrode 31 onto the driving substrate 10 may at least partially coincide with that of the pixel definition layer 20 on the driving substrate 10. In other words, the anode electrode 31 and the pixel definition layer 20 may at least partially coincide on the driving substrate 10 in the vertical direction. The second connecting wire 60 may be electrically connected to the anode electrode 31 by a jumper wire through the second via 23. The electrical signal transmission may be carried out between the anode electrode 31 and the second connecting wire 60. The second connecting wire 60 may be configured as a backup signal wire to be electrically connected to other components of the display panel, so as to realize signal transmission between the anode electrode 31 and the other components. The other components here may be touch layers.

In some embodiments, as illustrated in FIG. 3, the spacer structure 40 may include the body portion 401 and a second reinforcing portion 403. The second reinforcing portion 403 may be formed by extending from the body portion 401 towards a side away from the pixel aperture 21. The width of the second reinforcing portion 403 may be greater than that of the body portion 401 in a direction from the pixel aperture 21 to the extension region 12. The second connecting wire 60 may be connected to the second reinforcing portion 403. Through forming the second reinforcing portion 403 on the spacer structure 40, a connection strength between the second connecting wire 60 and the spacer structure 40 may be increased, and a risk of the second connecting wire 60 disconnecting from the spacer structure 40 due to the stretching of the display panel may be reduced, thereby increasing a connection stability between the second connecting wire 60 and the spacer structure 40.

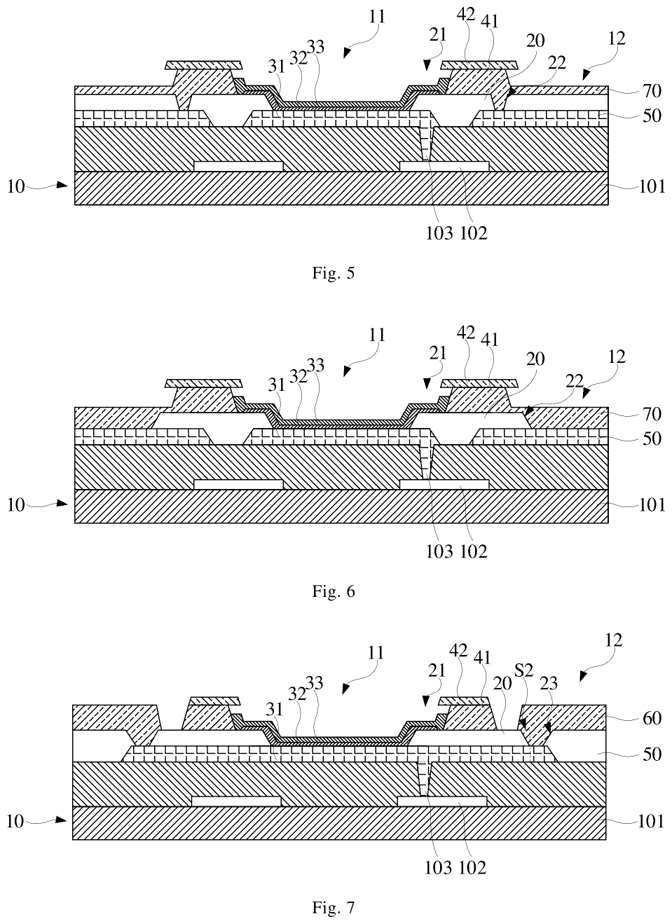

In some embodiments, as illustrated in FIG. 5 and FIG. 6, the display panel may further include a third connecting wire 70 correspondingly arranged with the first connecting wire 50. The third connecting wire 70 may extend from the extension region 12 to the pixel region 11, and may be electrically connected to the metal layer 41. The third connecting wire 70 and the metal layer 41 may be formed by deposition. The third connecting wire 70 and the metal layer 41 may be of an integral structure. A portion of the third connecting wire 70 may be reused as the metal layer 41, or a portion of the metal layer 41 may be reused as the third connecting wire 70. The third connecting wire 70 may transmit a same cathode electrode 33 signal as the first connecting wire 50. The third connecting wire 70 may be on a same vertical plane as the first connecting wire 50, so that the third connecting wire 70 and the first connecting wire 50 may be electrically connected to the metal layer 41 simultaneously. The third connecting wire 70 and the metal layer 41 may be formed by simultaneous deposition processes with the same material, thereby saving manufacturing procedures.

In some embodiments, as illustrated in FIG. 5 and FIG. 6, the orthographic projection of the first connecting wire 50 onto the driving substrate 10 may coincide with the orthographic projection of the pixel definition layer 20 onto the driving substrate 10, so as to form the first coinciding region S1. As illustrated in FIG. 5, there may be the pixel definition layer 20 between the third connecting wire 70 and the first connecting wire 50, such that the third connecting wire 70 may be separated from the first connecting wire 50. The pixel definition layer 20 may form the first via 22 in the pixel region 11 (FIG. 5) and/or in the extension region 12 (FIG. 6). As illustrated in FIG. 5, the metal layer 41 may pass through the first via 22 to be electrically connected to the first connecting wire 50. As illustrated in FIG. 6, the third connecting wire 70 may pass through the first via 22 to be electrically connected to the first connecting wire 50. Since the metal layer 41 surrounds the peripheral side of the pixel aperture 21, and the first connecting wire 50, the second connecting wire 60 and the third connecting wire 70 transmit the electrical signals of adjacent sub-pixels 30, and the first connecting wire 50, the second connecting wire 60 and the third connecting wire 70 need to be stretched, thus the sizes of the first connecting wire 50, the second connecting wire 60 and the third connecting wire 70 may be less than that of the metal layer 41. The pixel definition layer 20 may completely coincide with the first connecting wire 50, so that the pixel definition layer 20 may cover the extension region 12. The pixel definition layer 20 may protect the first connecting wire 50, the second connecting wire 60, and the third connecting wire 70, and may absorb stresses of the first connecting wire 50, the second connecting wire 60 and the third connecting wire 70 when being stretched. Therefore, through arranging the first via 22 in the pixel region 11 and/or the extension region 12, the metal layer 41 or the third connecting wire 70 may be enabled to jump wires and be electrically connected to the first connecting wire 50.

In some embodiments, as illustrated in FIG. 5, when the first via 22 is arranged in the pixel definition layer 20 of the pixel region 11, the metal layer 41 may pass through the first via 22 to electrically connect with the first connecting wire 50. There may be the pixel definition layer 20 between the third connecting wire 70 and the first connecting wire 50, so that the third connecting wire 70 may be insulated from the first connecting wire 50. In this way, the electrical signals of the metal layer 41 may be separately transmitted by the first connecting wire 50 and the third connecting wire 70 to the metal layer 41 of an adjacent spacer structure 40. Through such a design, a signal transmission area may be increased, thereby reducing a voltage drop of the display panel and increasing the display quality.

In some other embodiments, as illustrated in FIG. 6, when the first via 22 is arranged in the pixel definition layer 20 of the extension region 12, the third connecting wire 70 may pass through the first via 22 to be electrically connected to the first connecting wire 50. There may be the pixel definition layer 20 between the third connecting wire 70 and the first connecting wire 50, so that the third connecting wire 70 may be separated from the first connecting wire 50. Thus, an electrical signal from the metal layer 41 may be first transmitted to the third connecting wire 70. After the third connecting wire 70 jumps wires, the electrical signal may be simultaneously transmitted by the first connecting wire 50 and the third connecting wire 70. Through such a design, the signal transmission area may also be increased, thereby reducing the voltage drop of the display panel and increasing the display quality.

In some embodiments, as illustrated in FIG. 4, a width of the insulating layer 42 may be greater than that of the metal layer 41. The metal layer 41 may gradually decrease in a direction from a position close to the pixel definition layer 20 to another position away from the pixel definition layer 20. The insulating layer 42 may gradually decrease in a direction from a position close to the metal layer 41 to another position away from the metal layer 41. A shielding portion may be formed on a side of the metal layer 41 close to the pixel aperture 21, and another shielding portion may be formed on another side of the metal layer 41 close to the extension region 12. In this way, during an evaporation process, an evaporation source may be enabled to perform evaporation at a certain evaporation angle to form different layer structures. The layer structures may include the light-emitting layer 32 and the cathode electrode 33.

In some other embodiments, as illustrated in FIG. 7, on the side of the spacer structure 40 facing the extension region 12, a side surface of the insulating layer 42 may be on a same plane with that of the metal layer 41. On one side of the spacer structure 40 facing the pixel aperture 21, the insulating layer 42 may extend beyond the metal layer 41 along the length direction of the driving substrate 10. The shielding portion may be formed on the side of the metal layer 41 close to the pixel aperture 21. In this way, during the evaporation process, the evaporation source may be enabled to perform evaporation at a certain evaporation angle to form different layer structures. The layer structures may include the light-emitting layer 32 and the cathode electrode 33.

In some embodiments, a metal material layer may be first deposited on the pixel definition layer 20. The deposited metal material layer may extend to the extension region 12. The metal material layer may be etched to form the metal layer 41 and the second connecting wire 60 respectively. In a case where shielding portions are respectively formed on the side of the metal layer 41 close to the pixel aperture 21 and the another side of the metal layer 41 close to the extension region 12, anisotropic etching may be adopted to etch the metal material layer, shielding portions may be formed on both sides of the spacer structure 40. In a case where a shielding portion is formed on the side of the metal layer 41 close to the extension region 12, anisotropic etching may be adopted on the side of the metal layer 41 close to the pixel aperture 21, and anisotropic etching, dry etching, wet etching, or the like may be adopted on the side of the metal layer 41 close to the extension region 12.

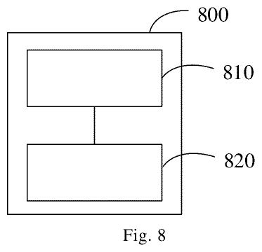

As illustrated in FIG. 8, a display apparatus 800 is further provided in some embodiments of the present disclosure. The display apparatus 800 may include the above-mentioned display panel 810 and a power supply 820. The power supply 820 may be configured to provide power for the display panel 810 and other components of the display apparatus 800. The power supply 820 may be a battery or a power adapter. The battery may supply power to the device when there is no external power source connected. The power adapter may be configured to connect to an external power source, such as a utility grid, or the like, and to convert external electrical energy into electrical energy suitable for the operation of the display panel 810, which is not limited herein.

The metal layer 41 may be electrically connected to the first connecting wire 50 by the jumper wire through the first via 22, so as to conduct the electrical signal transmission between the metal layer 41 and the first connecting wire 50. The pixel definition layer 20 may protect a portion of the first connecting wire 50, and the junction between the metal layer 41 and the first connecting wire 50. When the display panel is stretched, the risk of disconnection between the metal layer 41 and the first connecting wire 50 may be reduced, thereby increasing the effectiveness and stability of the signal transmission of the first connecting wire 50. The second connecting wire 60 may be electrically connected to the anode electrode 31 by the jumper wire through the second via 23, so as to conduct the electrical signal transmission between the anode electrode 31 and the second connecting wire 60. The second connecting wire 60 may be configured as the backup signal wire to be electrically connected to other components of the display panel, so as to realize the signal transmission between the anode electrode 31 and other components.

In the present disclosure, unless otherwise definitely specified and limited, the terms “arranged” (provided), “connected” or the like should be understood in a broad sense. For example, these terms may refer to fixed connections or detachable connections, or integration into a single body. In some embodiments, these terms may refer to mechanical connections or electrical connections. In some embodiments, these terms may refer to direct connections or indirect connections through intermediate mediums, and these terms may refer to internal connection between two components or interaction relationship between two components. For those of ordinary skills in the art, specific meanings of the above-mentioned terms in the present disclosure may be understood according to specific circumstances.

In the description of the present disclosure, description with reference to the term “some embodiments” or the like means that, the specific features, structures, materials, characteristics described in conjunction with an embodiment or an example may be included in at least one embodiment of the present disclosure. In the present specification, schematic expressions of the above-mentioned terms do not necessarily refer to the same embodiment or example. Moreover, the specific features, structures, materials or characteristics described may be combined in any of the one or more embodiments or examples in a suitable manner. In addition, where there is no contradiction, those skilled in the art may combine and integrate different embodiments or examples as well as the features of different embodiments or examples described in the present specification.

Although the embodiments of the present disclosure have been illustrated and described above, it should be appreciated that, the above-mentioned embodiments are exemplary and should not be construed as limiting the present disclosure. Those of ordinary skill in the art may make changes, modifications, substitutions, and variations to the above-mentioned embodiments within the scope of the present disclosure. Therefore, any changes or modifications made in accordance with the claims and specifications of the present disclosure shall fall within the scope covered by the present patent.

1. A display panel, comprising:
a driving substrate, forming a pixel region and an extension region;
a pixel definition layer, arranged on the driving substrate; wherein the pixel definition layer is configured to protrude from the driving substrate to define a pixel aperture;
a sub-pixel, arranged in the pixel aperture; wherein the sub-pixel comprises an anode electrode, a light-emitting layer and a cathode electrode; the anode electrode, the light-emitting layer and the cathode electrode are stacked from a position close to the driving substrate to another position away from the driving substrate;
a spacer structure, arranged on the pixel definition layer and located on a peripheral side of the pixel aperture to separate the pixel region from the extension region; wherein the spacer structure comprises a metal layer and an insulating layer, the metal layer and the insulating layer are stacked from a position close to the pixel definition layer to another position away from the pixel definition layer; and
a first connecting wire, arranged on the driving substrate; wherein the first connecting wire extends from the extension region to the pixel region; the first connecting wire is insulated from the anode electrode; an orthographic projection of the first connecting wire onto the driving substrate at least partially coincides with an orthographic projection of the pixel definition layer onto the driving substrate, so as to form a first coinciding region; the pixel definition layer forms a first via in the first coinciding region; the metal layer electrically connects with the first connecting wire through the first via.

2. The display panel as claimed in claim 1, wherein
a portion of the anode electrode extends from the pixel region to the extension region; on a side of the spacer structure facing the extension region, an orthographic projection of the anode electrode onto the driving substrate at least partially coincides with that of the pixel definition layer onto the driving substrate, so as to form a second coinciding region; the pixel definition layer forms a second via in the second coinciding region;
the display panel further comprises a second connecting wire, the second connecting wire is arranged on a side of the pixel definition layer opposite to the driving substrate, and the second connecting wire is insulated from the metal layer, the second connecting wire passes through the second via to electrically connect with the anode electrode.

3. The display panel as claimed in claim 1, wherein
the display panel further comprises a third connecting wire; the third connecting wire extends from the extension region to the pixel region, so as to electrically connect with the metal layer; the third connecting wire and the metal layer are of an integral structure;
a portion of the third connecting wire is reused as the metal layer; or, a portion of the metal layer is reused as the third connecting wire.

4. The display panel as claimed in claim 3, wherein
the pixel definition layer forms the first via in the pixel region; the metal layer passes through the first via to electrically connect with the first connecting wire; the pixel definition layer is provided between the third connecting wire and the first connecting wire, such that the third connecting wire is separated from the first connecting wire.

5. The display panel as claimed in claim 3, wherein
the pixel definition layer forms the first via in the extension region at a side of the spacer structure opposite to the pixel aperture; the third connecting wire passes through the first via to electrically connect with the first connecting wire.

6. The display panel as claimed in claim 1, wherein
the spacer structure comprises a body portion and a first reinforcing portion; the first reinforcing portion extends from the body portion towards a side away from the pixel aperture; a size of the first reinforcing portion is greater than that of the body portion in a direction from the pixel aperture to the extension region; the first connecting wire is connected to the first reinforcing portion.

7. The display panel as claimed in claim 2, wherein
the spacer structure comprises a body portion and a second reinforcing portion; the second reinforcing portion extends from the body portion towards a side away from the pixel aperture; a size of the second reinforcing portion is greater than that of the body portion in a direction from the pixel aperture to the extension region; the second connecting wire is connected to the second reinforcing portion.

8. The display panel as claimed in claim 1, wherein
the width of the insulating layer is greater than that of the metal layer ; the metal layer gradually decreases in a direction from a position close to the pixel definition layer to another position away from the pixel definition layer; the insulating layer gradually decreases in a direction from a position close to the metal layer to another position away from the metal layer.

9. The display panel as claimed in claim 1, wherein
on a side of the spacer structure facing the extension region, a side surface of the insulating layer is on a same plane with that of the metal layer; and, on another side of the spacer structure facing the pixel aperture, the insulating layer extends beyond the metal layer along a length direction of the driving substrate.

10. The display panel as claimed in claim 1, wherein
the first connecting wire and the anode electrode are arranged in a same layer on the driving substrate.

11. A display apparatus, comprising a display panel and a power supply that are electrically connected to each other,
wherein the display panel comprises:
a driving substrate, forming a pixel region and an extension region;
a pixel definition layer, arranged on the driving substrate; wherein the pixel definition layer is configured to protrude from the driving substrate to define a pixel aperture;
a sub-pixel, arranged in the pixel aperture; wherein the sub-pixel comprises an anode electrode, a light-emitting layer and a cathode electrode; the anode electrode, the light-emitting layer and the cathode electrode are stacked from a position close to the driving substrate to another position away from the driving substrate;
a spacer structure, arranged on the pixel definition layer and located on a peripheral side of the pixel aperture to separate the pixel region from the extension region; wherein the spacer structure comprises a metal layer and an insulating layer, the metal layer and the insulating layer are stacked from a position close to the pixel definition layer to another position away from the pixel definition layer; and
a first connecting wire, arranged on the driving substrate; wherein the first connecting wire extends from the extension region to the pixel region; the first connecting wire is insulated from the anode electrode; an orthographic projection of the first connecting wire onto the driving substrate at least partially coincides with an orthographic projection of the pixel definition layer onto the driving substrate, so as to form a first coinciding region; the pixel definition layer forms a first via in the first coinciding region; the metal layer electrically connects with the first connecting wire through the first via.

12. The display apparatus as claimed in claim 11, wherein
a portion of the anode electrode extends from the pixel region to the extension region; on a side of the spacer structure facing the extension region, an orthographic projection of the anode electrode onto the driving substrate at least partially coincides with that of the pixel definition layer onto the driving substrate, so as to form a second coinciding region; the pixel definition layer forms a second via in the second coinciding region;
the display panel further comprises a second connecting wire, the second connecting wire is arranged on a side of the pixel definition layer opposite to the driving substrate, and the second connecting wire is insulated from the metal layer, the second connecting wire passes through the second via to electrically connect with the anode electrode.

13. The display apparatus as claimed in claim 11, wherein
the display panel further comprises a third connecting wire; the third connecting wire extends from the extension region to the pixel region, so as to electrically connect with the metal layer; the third connecting wire and the metal layer are of an integral structure;
a portion of the third connecting wire is reused as the metal layer; or, a portion of the metal layer is reused as the third connecting wire.

14. The display apparatus as claimed in claim 13, wherein
the pixel definition layer forms the first via in the pixel region; the metal layer passes through the first via to electrically connect with the first connecting wire; the pixel definition layer is provided between the third connecting wire and the first connecting wire, such that the third connecting wire is separated from the first connecting wire.

15. The display apparatus as claimed in claim 13, wherein
the pixel definition layer forms the first via in the extension region at a side of the spacer structure opposite to the pixel aperture; the third connecting wire passes through the first via to electrically connect with the first connecting wire.

16. The display apparatus as claimed in claim 11, wherein
the spacer structure comprises a body portion and a first reinforcing portion; the first reinforcing portion extends from the body portion towards a side away from the pixel aperture; a size of the first reinforcing portion is greater than that of the body portion in a direction from the pixel aperture to the extension region; the first connecting wire is connected to the first reinforcing portion.

17. The display apparatus as claimed in claim 12, wherein
the spacer structure comprises a body portion and a second reinforcing portion; the second reinforcing portion extends from the body portion towards a side away from the pixel aperture; a size of the second reinforcing portion is greater than that of the body portion in a direction from the pixel aperture to the extension region; the second connecting wire is connected to the second reinforcing portion.

18. The display apparatus as claimed in claim 11, wherein
the width of the insulating layer is greater than that of the metal layer; the metal layer gradually decreases in a direction from a position close to the pixel definition layer to another position away from the pixel definition layer; the insulating layer gradually decreases in a direction from a position close to the metal layer to another position away from the metal layer.

19. The display apparatus as claimed in claim 11, wherein
on a side of the spacer structure facing the extension region, a side surface of the insulating layer is on a same plane with that of the metal layer; and, on another side of the spacer structure facing the pixel aperture, the insulating layer extends beyond the metal layer along a length direction of the driving substrate.

20. The display apparatus as claimed in claim 11, wherein
the first connecting wire and the anode electrode are arranged in a same layer on the driving substrate.
